(19) United States
(12) Patent Application Publication
(10) Pub. No.: US 2026/0332134 A1
(43) Pub. Date: Oct. 22, 2026

(54) TRANSFERRING INFORMATION BETWEEN CLOCK DOMAINS IN AN ELECTRONIC SYSTEM

(71) Applicant: Skyworks Solutions, Inc., Irvine, CA (US)

(72) Inventor: David W. Vinke, Happy Valley, OR (US)

(21) Appl. No.: 19/185,107

(22) Filed: Apr. 21, 2025

Related U.S. Application Data
(60) Provisional application No. 63/637,330, filed on Apr. 22, 2024.

(51) Int. Cl. H03K 3/037; G06F 1/12

(52) U.S. Cl. CPC H03K 3/037; G06F 1/12

(57) ABSTRACT

A method for transferring data (e.g., a single bit of data) from a first clock domain to a second clock domain includes receiving the data in the first clock domain and generating, by a clock generator, a clock signal having a frequency that is a multiple of a frequency of the second clock domain. The method further includes sampling, by using a sequential circuit including a first flip-flop clocked by the clock signal, the data with the first flip-flop to transfer the data to the second clock domain.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of the present disclosure relate to electronic systems, and in particular, to a method and an apparatus for transferring a single-bit signal or data from a first clock domain to a second clock domain, and a corresponding synchronous bus interface.

### Description of the Related Technology

In electronic systems, there may be a need for single-bit signals and/or data to be transferred from one clock domain to another, i.e. between different clock domains.

For instance, a two-flip-flop synchronizer may be used for transferring single bit signals between asynchronous clock domains. Thereby, it has been shown in practice that the first flip-flop may occasionally become metastable, but the second flop will rarely become metastable. In such a case, the mean time between failures (MTBF) may be calculated and may be, in some cases, acceptable compared to the lifetime of the product. However, if the clock domains are not asynchronous but periodic, then the two-flip-flop synchronizer may have a MTBF that is orders of magnitude higher than expected. One method to transfer single bit signals between periodic clock domains may be to use an extra clock domain that is truly asynchronous to the first two clock domains. The two-flip-flop synchronizer may then be used to transfer signals from the launch clock domain to the extra, i.e. third, clock domain and from the extra clock domain to the capture clock domain.

### SUMMARY

In some aspects, the techniques described herein relate to a method for transferring at least a first signal from a first clock domain to a second clock domain, the method including: receiving a first signal representing a first data bit in the first clock domain; generating, by a clock generator, a clock signal having a frequency that is a multiple of a frequency of the second clock domain; sampling, by using a sequential circuit including a first flip-flop clocked by the clock signal, the first signal with the first flip-flop to transfer the first signal to the second clock domain.

In some aspects, the techniques described herein relate to a method wherein the first clock domain and the second clock domain are periodic with each other.

In some aspects, the techniques described herein relate to a method wherein the frequency of the clock signal is twice the frequency of the second clock domain.

In some aspects, the techniques described herein relate to a method wherein the clock signal is generated so that there is one clock pulse in each period of the second clock domain.

In some aspects, the techniques described herein relate to a method wherein, in each period of the second clock domain, a pulse of the clock signal is aligned with a rising edge or a falling edge of the second clock domain based on a value of a phase signal.

In some aspects, the techniques described herein relate to a method wherein the phase signal is derived so that positive edges of the clock signal are farther away from positive edges of the first clock domain.

In some aspects, the techniques described herein relate to a method further including outputting the first signal in the second clock domain.

In some aspects, the techniques described herein relate to a method wherein one or more additional signals representing one or more additional data bits are to be transferred from the first clock domain to the second clock domain, the first signal is to indicate that the one or more additional signals to be transferred are valid, the sequential circuit includes a number of second flip-flops clocked by the clock signal, and the method further includes: sampling one or more additional signals with the number of second flip-flops; and gating a respective output of the number of second flip-flops by the first signal transferred to the second clock domain to transfer the one or more additional signals to the second clock domain.

In some aspects, the techniques described herein relate to a method further including outputting the transferred one or more additional signals in the second clock domain.

In some aspects, the techniques described herein relate to a method wherein the first signal indicates by its signal level whether or that the one or more additional signals to be transferred are valid.

In some aspects, the techniques described herein relate to a method wherein the first signal indicates by its changing state whether or that the one or more additional signals to be transferred are valid.

In some aspects, the techniques described herein relate to a method wherein a path between the first clock domain and the second clock domain is timed in static timing analysis (STA).

In some aspects, the techniques described herein relate to an apparatus for transferring at least a first signal from a first clock domain to a second clock domain, the apparatus including: a clock generator configured to generate a clock signal having a frequency that is a multiple of a frequency of the second clock domain; and a sequential circuit including a first flip-flop configured to receive a first signal representing a first data bit in the first clock domain and to receive the clock signal, the sequential circuit being configured to sample the first signal with the first flip-flop to transfer the first signal to the second clock domain.

In some aspects, the techniques described herein relate to an apparatus wherein the first clock domain and the second clock domain are periodic with each other.

In some aspects, the techniques described herein relate to an apparatus wherein the frequency of the clock signal is twice the frequency of the second clock domain.

In some aspects, the techniques described herein relate to an apparatus wherein the clock signal is generated so that there is one clock pulse in each period of the second clock domain.

In some aspects, the techniques described herein relate to an apparatus wherein a pulse of the clock signal is aligned with a rising edge or a falling edge of the second clock domain based on a value of a phase signal.

In some aspects, the techniques described herein relate to an apparatus wherein the phase signal is derived so that positive edges of the clock signal are farther away from positive edges of the first clock domain.

In some aspects, the techniques described herein relate to an apparatus further including an output configured to output the transferred first signal in the second clock domain.

In some aspects, the techniques described herein relate to an apparatus wherein one or more additional signals representing one or more additional data bits are to be transferred from the first clock domain to the second clock domain, the first signal is to indicate that the one or more additional signals to be transferred are valid, the sequential circuit includes a number of second flip-flops clocked by the clock signal, and the apparatus is further configured to: sample the one or more additional signals with the number of second flip-flops; and gate a respective output of the number of second flip-flops by the first signal transferred to the second clock domain to transfer the one or more additional signals to the second clock domain.

In some aspects, the techniques described herein relate to an apparatus further including an output configured to output the transferred one or more additional signals in the second clock domain.

In some aspects, the techniques described herein relate to an apparatus wherein the first signal indicates by its signal level whether or that the one or more additional signals to be transferred are valid.

In some aspects, the techniques described herein relate to an apparatus wherein the first signal indicates by its changing state whether or that the one or more additional signals to be transferred are valid.

In some aspects, the techniques described herein relate to an apparatus wherein a path between the first clock domain and the second clock domain is timed in static timing analysis (STA).

In some aspects, the techniques described herein relate to a synchronous bus interface for transferring at least one of a first signal and data from a first clock domain to a second clock domain, the synchronous bus interface including: a clock generator configured to generate a clock signal having a frequency that is a multiple of a frequency of the second clock domain; a sequential circuit coupled to the clock generator and including a first flip-flop configured to receive a first signal in the first clock domain and to receive the clock signal, the sequential circuit being configured to sample the first signal with the first flip-flop to transfer the first signal to the second clock domain; and an output coupled to the sequential circuit.

In some aspects, the techniques described herein relate to a synchronous bus interface wherein the first clock domain and the second clock domain are periodic with each other.

In some aspects, the techniques described herein relate to a synchronous bus interface wherein the frequency of the clock signal is twice the frequency of the second clock domain.

In some aspects, the techniques described herein relate to a synchronous bus interface wherein the clock signal is generated so that there is one clock pulse in each period of the second clock domain.

In some aspects, the techniques described herein relate to a synchronous bus interface wherein a pulse of the clock signal is aligned with a rising edge or a falling edge of the second clock domain based on a value of a phase signal.

In some aspects, the techniques described herein relate to a synchronous bus interface wherein the phase signal is derived so that positive edges of the clock signal are farther away from positive edges of the first clock domain.

In some aspects, the techniques described herein relate to a synchronous bus interface wherein one or more additional signals representing one or more additional data bits are to be transferred from the first clock domain to the second clock domain, the first signal is to indicate that the one or more additional data bits to be transferred are valid, the sequential circuit includes a number of second flip-flops clocked by the clock signal, and the synchronous bus interface is further configured to: sample the one or more additional signals with the number of second flip-flops; and gate a respective output of the number of second flip-flops by the first signal transferred to the second clock domain to transfer the one or more additional signals to the second clock domain.

### BRIEF DESCRIPTION OF THE DRAWINGS

FIG. 1 illustrates in a schematic block diagram an exemplary apparatus for transferring a single-bit signal and/or data from a first clock domain to a second clock domain according to an embodiment of the present disclosure.

FIG. 2 illustrates in a schematic block and/or circuit diagram an exemplary implementation of the apparatus in a synchronous bus interface, for transferring a single-bit signal and/or data from a first clock domain to a second clock domain according to an embodiment.

FIG. 3 illustrates in a schematic block and/or circuit diagram an exemplary apparatus and/or the synchronous bus interface for a forward transfer of a single-bit signal and/or data from a first clock domain to a second clock domain according to an embodiment.

FIG. 4 illustrates in a schematic block and/or circuit diagram an exemplary apparatus and/or the synchronous bus interface for a reverse transfer of a single-bit signal and/or data from a first clock domain to a second clock domain according to an embodiment.

FIG. 5 illustrates in a schematic block and/or circuit diagram another exemplary apparatus and/or the synchronous bus interface for transferring a single-bit signal and/or data from a first clock domain to a second clock domain according to an embodiment.

FIG. 6 illustrates in a schematic block and/or circuit diagram an exemplary apparatus and/or the synchronous bus interface for a forward transfer of a single-bit signal and/or data from a first clock domain to a second clock domain according to an embodiment.

FIG. 7 illustrates in a schematic block and/or circuit diagram an exemplary apparatus and/or the synchronous bus interface for a reverse transfer of a single-bit signal and/or data from a first clock domain to a second clock domain according to an embodiment.

FIG. 8 illustrates in a timing diagram a principle of transferring a single-bit signal and/or data from one clock domain to another. FIG. 8 is presented in four separate parts as FIGS. 8-1, 8-2, 8-3, and 8-4, which are included on separate sheets.

FIG. 9 illustrates in a timing diagram a principle of transferring a single-bit signal and/or data from one clock domain to another. FIG. 9 is presented in four separate parts as FIGS. 9-1, 9-2, 9-3, and 9-4, which are included on separate sheets

FIG. 10 illustrates in a timing diagram a principle of transferring a single-bit signal and/or data from one clock domain to another. FIG. 10 is presented in four separate parts as FIGS. 10-1, 10-2, 10-3, and 10-4, which are included on separate sheets

FIG. 11 illustrates in a timing diagram a principle of transferring a single-bit signal and/or data from one clock domain to another. FIG. 11 is presented in four separate parts as FIGS. 11-1, 11-2, 11-3, and 11-4, which are included on separate sheets

FIG. 12 illustrates in a schematic block and/or circuit diagram an example of a clock generator according to an embodiment.

FIG. 13 illustrates in a flow chart an exemplary method for transferring a single-bit signal and/or data from a first clock domain to a second clock domain according to an embodiment.

FIG. 14 illustrates a schematic block diagram of an example of a system that can include any of the circuitry described herein for transferring a single-bit signal and/or data from a first clock domain to a second clock domain, according to an embodiment of the present disclosure.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

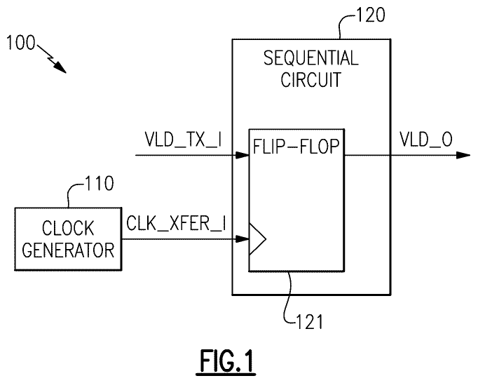

FIG. 1 illustrates in a schematic block diagram an exemplary apparatus 100 for transferring a single-bit signal and/or data from a first clock domain to a second clock domain according to an embodiment. As used herein, the first clock domain may also be referred to as launch clock domain, and the second clock domain may also be referred to as capture clock domain. For example, such apparatus 100 may be used in an electronic device and/or electronic system, in which data, i.e. multiple bits of a same bus or the like, and/or single-bit signals are to be transferred from one clock domain to another. Merely by way of example, such apparatus 100 may be used may be used in at least one of a data processor, an integrated circuit, a microcontroller, an application-specific integrated circuit, ASIC, a field programmable gate array (FPGA), or the like.

The first clock domain and the second clock domain may be periodic with each other. Also, the first clock domain and the second clock domain may be synchronous. For example, a first clock of the first clock domain and a second clock of the second clock domain may be derived from the same source, e.g. by using different phase-locked loops (PLLs) or the like, wherein the source of the clocks is not limited herein. It is understood that the first clock domain and the second clock domain may be different divisors and/or multiples of the same source. Merely by way of example, in order to better illustrate the periodic relationship between the two clock domains, the first clock domain may be or may comprise a 49.152 MHz clock generated by a multiply by 32 of a 1.536 MHz clock, and the second clock domain may be or may comprise a 48 MHz clock generated by a divide by 4 of a 192 MHz clock. The 1.536 MHz clock may be generated by a divide by 125 of the 192 MHz clock. Merely by way of example, clk_192m may have a frequency of 192 MHz and a period of 5.2083 ns, clk_96m may have a frequency of 96 MHz and a period of 10.4167 ns, clk_48m may have a frequency of 48 MHz and a period of 20.8333 ns, clk_1p536m may have a frequency of 1.536 MHz and a period of 651.0417 ns, and clk_pdm_49m may have a frequency of 49.152 MHz and a period of 20.3450 ns. In this example, 125 cycles of clk_48m equals 128 cycles of clk_pdm_49m. Further, a “tt unit” may be defined to be 1/125 of a clk_pdm_49m cycles, or about 0.1628 ns. Further, 128 tt_units equal 20.8333ns equals 1 clk_48m cycle. Over time the edges of clk_pdm_49m and clk_48m may move in integer multiples of tt units relative to each other assuming no jitter. Every 125 clk_48m cycles the edges may have the same relative offset. That is, the first clock domain and the second clock domain are periodic with each other. It is to be understood that the frequencies mentioned above are merely intended for better illustration and are only exemplary and that the principle described herein can also be applied to other clock domains having other frequencies and that are periodic with each other. Although the principle described herein is not limited to the exemplary frequencies, for better illustration, the first clock domain may also be referred to herein as clk_pdm_49m domain and the second clock domain as clk_48m domain.

In this disclosure, it is proposed to efficiently transfer a single-bit signal and/or data from the first clock domain to the second clock domain. The reverse transfer from the second clock domain to the first clock domain is also proposed. Embodiments of the present disclosure may provide for transferring a single-bit signal and/or data between clock domains without causing, or at least less causing, metastability or timing failures.

The apparatus 100 comprises a clock generator 110 and a sequential circuit 120 coupled to each other.

The clock generator 110 is configured to generate a clock signal clk_xfer_i having a frequency that is a multiple of a frequency of one of first and second clock domain, and particularly of the second clock domain clk_48m. In at least some embodiments, the frequency of the clock signal clk_xfer_i is, at least substantially, twice the frequency of the second clock domain clk_48m, wherein this is not limited herein. Referring to the above examples of frequencies, the clock signal clk_xfer_i may be generated based on pulses of a 96 MHz clock, which is twice of the 48 MHz clock of the second clock domain clk_48m. It is noted that this frequency is merely exemplary and is intended to facilitate understanding, and therefore not limited herein. As used herein, the clock signal clk_xfer_i may also be referred to as transfer clock.

The sequential circuit 120 comprises at least one data storage element, e.g. a first flip-flop 121. The first flip-flop 121 is configured to receive a single-bit signal vld_tx_i in the first clock domain clk_pdm_49m. Further, the first flip-flop 121 is configured to receive the clock signal clk_xfer_i. The sequential circuit 120 is configured to sample the single-bit signal vld_tx_i with the first flip-flop 121 to transfer the single-bit signal to the second clock domain clk_48m. In other words, a single-bit signal may be transferred from the first clock domain clk_pdm_49m to the second clock domain clk_48m by sampling the single-bit signal with a data storage element, e.g. the first flip-flop 121, clocked by the clock signal clk_xfer_i, i.e. the transfer clock, and then capturing the output of this data storage element, e.g. the first flip-flop 121, in the second clock domain clk_48m.

According to an embodiment of the present disclosure, since the clock signal, i.e. the transfer clock, is synchronous with the second clock domain clk_48m, power consumption of the apparatus 100 and/or an electronic device comprising the same may be reduced compared to using a two-flip-flop synchronizer with an extra, i.e. third, asynchronous clock, as there is no need for a further clock source constantly operated. Further, the clock signal, i.e. the transfer clock, being synchronous with the second clock domain clk_48m, may reduce latency compared to using an extra, i.e. third, asynchronous clock. Also, there is no need for a metastability hardened, additional flip-flop, or to rely on a mean time between failures (MTBF) calculation.

In at least some embodiments, the clock signal clk_xfer_i may be generated so that there is one clock pulse in each period of the second clock domain clk_48m.

Further, in at least some embodiments, in each period of the second clock domain clk_48m, a pulse of the clock signal clk_xfer_i may be aligned with a rising edge or a falling edge of the second clock domain clk_48m based on a value of a phase signal. For example, the phase signal may be derived so that positive edges of the clock signal clk_xfer_i are farther away from positive edges of the first clock domain clk_pdm_49m. For example, this may be provided by using two counters, i.e. a first counter and a second counter, each clocked by the second clock domain clk_48m. The first counter may count from a value I down to 0 and then reset back to I. The second counter may count from a value J down to 0, but may only count down when the first counter resets, otherwise it holds its value. The first counter gets reset to a value K, possibly different than I, when the positive edges of the first clock domain clk_pdm_49m and the second clock domain clk_48m align, wherein this is provided as the first and second clock domains are periodic with each other. The second counter gets reset to J at the same time. For instance, the phase signal may be taken as the least significant bit (LSB) of the second counter. The values of I, J, and K may be calculated to ensure that positive edges of the clock signal clk_xfer_i, i.e. the transfer clock, are far away from positive edges of the first clock domain clk_pdm_49m. The calculations may also account for a phase delay between the first clock domain clk_pdm_49m and the second clock domain clk_48m align, such as from a phase frequency detector of a PLL, as long as this delay is reasonably bounded.

In at least some embodiments, the apparatus 100 may be configured to output the single-bit signal in the second clock domain clk_48m. For example, the apparatus 100 may comprise at least one output, e.g. output node, configured to capture the single-bit signal transferred in the second clock domain clk_48m.

Further, in at least some embodiments, the apparatus 100 may be configured to time a path between the first clock domain clk_pdm_49m and the second clock domain clk_48m in static timing analysis (STA). This can be done since the two clock domains are synchronous. Also, the path from the first clock domain clk_pdm_49m to the transfer clock, i.e. the clock generating the clock signal clk_xfer_i, may be timed in STA since there is a known minimum time difference between their positive edges. Since all paths can be timed in STA the apparatus can be designed to be extremely reliable.

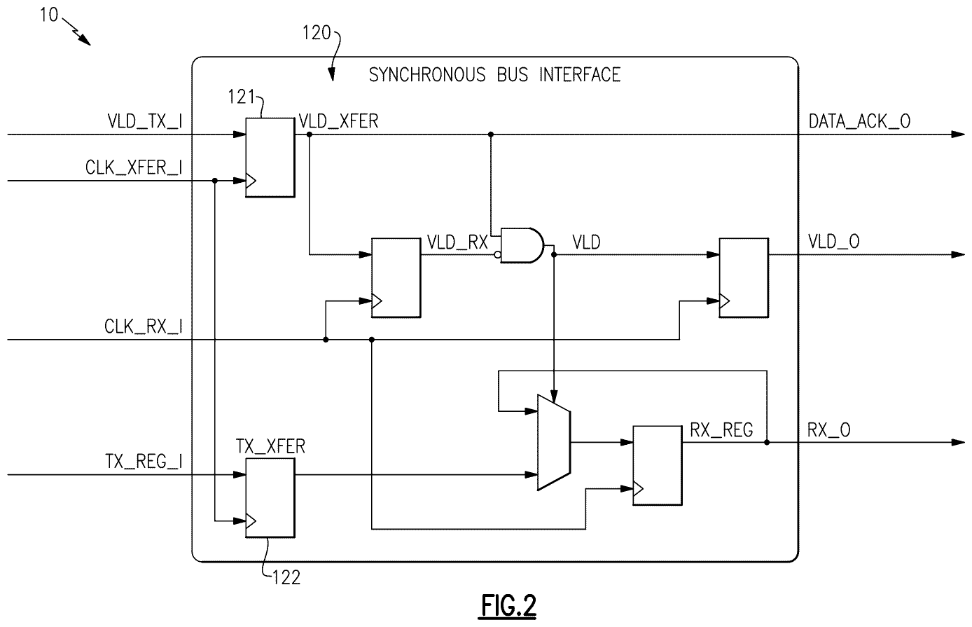

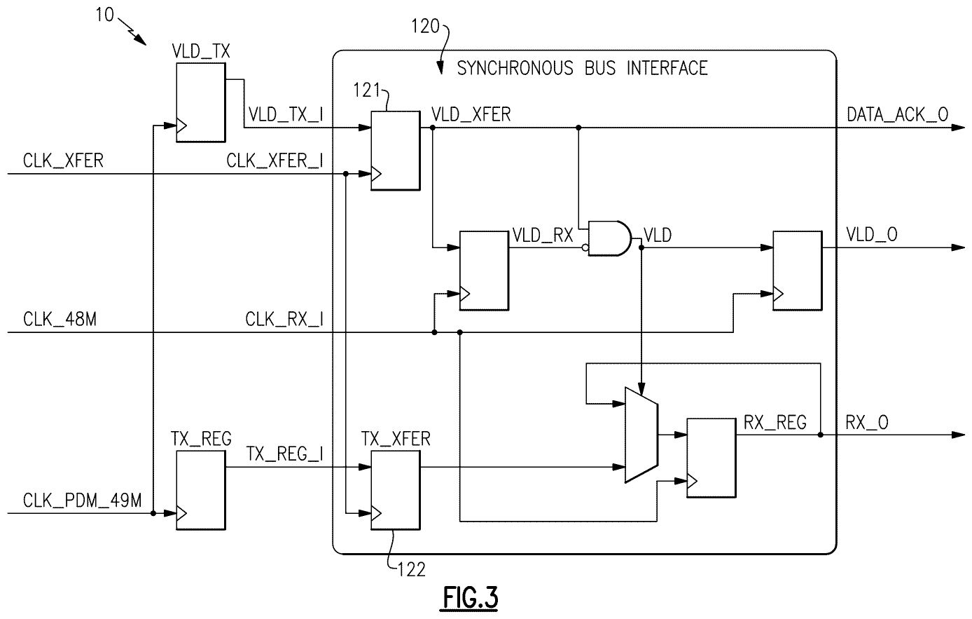

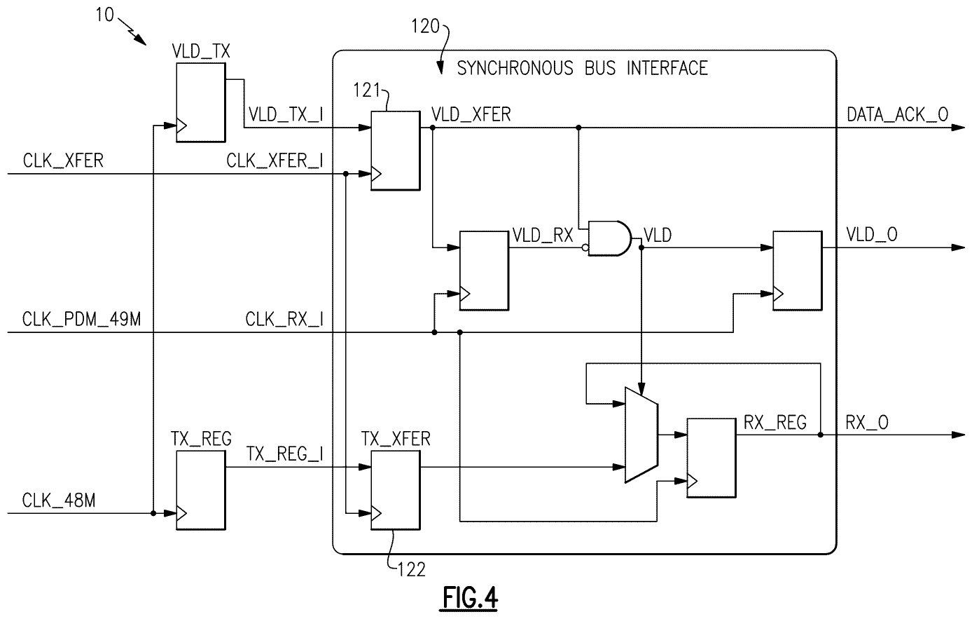

FIG. 2 illustrates in a schematic block and/or circuit diagram an exemplary implementation of the apparatus described herein, e.g. apparatus 100, in a synchronous bus interface 10. In addition to transferring single-bit signals from one clock domain to another, the apparatus, e.g. apparatus 100, and/or the synchronous bus interface 10 may be used to transfer data from the first clock domain clk_pdm_49m to the second clock domain clk_48m, which may also be referred to as forward transfer, and from the second clock domain clk_48m to the first clock domain clk_pdm_49m, which may also be referred to as reverse transfer. It is understood that for the reverse transfer the launch and capture clocks, i.e. the first clock domain and the second clock domain, are swapped as compared to the forward transfer.

For better illustration, in FIG. 2, the clock generator 110 is not explicitly illustrated, but its clock signal is denoted clk_xfer_i. As above, the apparatus, e.g. apparatus 100, and/or the synchronous bus interface 10 comprises the sequential circuit 120. It comprises a number of second flip-flops 122. It may also comprise a number of gates and further components. It may be understood that various functionalities associated with the transfer of the single-bit signal and/or the data from clock domain to another can be achieved with fewer or more components than depicted in FIG. 2.

According to an embodiment, data may be transferred from one clock domain to another, e.g. from the first clock domain clk_pdm_49m to the second clock domain clk_48m, or vice versa, by using a single-bit valid signal, which may indicate when new data is valid either by level or by toggling. The valid signal may be transferred as described above for apparatus 100 to generate or get a new valid signal in the second clock domain clk_48m. The data to be transferred may be sampled with the number of second flip-flops 122 clocked by the clock signal clk_xfer_i, i.e. the transfer clock and the outputs of the number of second flip-flops 122 may be gated by the transferred single-bit valid signal before being captured in the second clock domain clk_48m.

FIG. 3 illustrates in a schematic block and/or circuit diagram the apparatus, e.g. apparatus 100, and/or the synchronous bus interface 10 for the above-mentioned forward transfer.

In the example according to FIG. 3, the single-bit signal vld_tx_i denotes a valid strobe in the first clock domain clk_pdm_49m. Further, tx_reg_i denotes data from a register in the first clock domain clk_pdm_49m, and the valid strobe, i.e. the single-bit signal vld_tx_i, indicates when it is valid. In addition, vld_o denotes a valid strobe in the second clock domain clk_48m, and rx_o denotes the data in the second clock domain clk_48m. It is understood that either only the transferred single-bit signal vld_o, or only the transferred data rx_o, or both the transferred single-bit signal vld_o and the transferred data rx_o are captured and used at the output. It is noted that vld_o, rx_o and data_ack_o each denote an output of the apparatus, e.g. apparatus 100, and/or the synchronous bus interface 10. Accordingly, in at least some embodiments, the diagram the apparatus, e.g. apparatus 100, and/or the synchronous bus interface 10 may comprise one or more outputs configured to output the data, i.e. rx_o, in the second clock domain clk_48m.

In at least some embodiments, when data is to be transferred from the first clock domain clk_pdm_49m to the second clock domain clk_48m, the single-bit signal, i.e. vld_tx_i, is to indicate that data, i.e. tx_reg_i, to be transferred is valid. As mentioned above, the sequential circuit 120 comprises the number of second flip-flops 122 clocked by the clock signal clk_xfer_i. The apparatus, e.g. apparatus 100, and/or the synchronous bus interface 10 is configured to sample the data, i.e. tx_reg_i, with the number of second flip-flops 122. Further, the apparatus, e.g. apparatus 100, and/or the synchronous bus interface 10 is configured to gate a respective output of the number of second flip-flops 122 by the single-bit signal, i.e. vld_tx_i, transferred to the second clock domain clk_48m to transfer the data in the second clock domain clk_48m.

Referring to the above exemplary frequencies, since the first clock domain clk_pdm_49m is faster than the second clock domain clk_48m, the valid strobe can switch at most at 24.576 MHz, and data can be transferred at most at 12.288 MHz, wherein this is merely intended for better illustration and not limited herein.

FIG. 4 illustrates in a schematic block and/or circuit diagram the apparatus, e.g. apparatus 100, and/or the synchronous bus interface 10 for the above-mentioned reverse transfer.

In the example according to FIG. 4, the single-bit signal vld_tx_i denotes a valid strobe in the second clock domain clk_48m. Further, tx_reg_i denotes data from a register in the second clock domain clk_48m, and the valid strobe, i.e. the single-bit signal vld_tx_i, indicates when it is valid. In addition, vld_o denotes a valid strobe in the first clock domain clk_pdm_49m, and rx_o denotes the data in the first clock domain clk_pdm_49m. It is understood that either only the transferred single-bit signal vld_o, or only the transferred data rx_o, or both the transferred single-bit signal vld_o and the transferred data rx_o may be captured and used as output. It is noted that vld_o, rx_o and data_ack_o each denote an output of the apparatus, e.g. apparatus 100, and/or the synchronous bus interface 10. Accordingly, in at least some embodiments, the diagram the apparatus, e.g. apparatus 100, and/or the synchronous bus interface 10 may comprise one or more outputs configured to output the data, i.e. rx_o, in the first clock domain clk_pdm_49m.

In at least some embodiments, when data is to be transferred from the second clock domain clk_48m to the first clock domain clk_pdm_49m, the single-bit signal, i.e. vld_tx_i, is to indicate that data, i.e. tx_reg_i, to be transferred is valid. As mentioned above, the sequential circuit 120 comprises the number of second flip-flops 122 clocked by the clock signal clk_xfer_i. The apparatus, e.g. apparatus 100, and/or the synchronous bus interface 10 is configured to sample the data, i.e. tx_reg_i, with the number of second flip-flops 122. Further, the apparatus, e.g. apparatus 100, and/or the synchronous bus interface 10 is configured to gate a respective output of the number of second flip-flops 122 by the single-bit signal, i.e. vld_tx_i, transferred to the first clock domain clk_pdm_49m to transfer the data in the first clock domain clk_pdm_49m.

Referring to the above exemplary frequencies, since the first clock domain clk_pdm_49m is faster than the second clock domain clk_48m, the valid strobe can switch at most at 48 MHz, and data can be transferred at most at 24 MHz, wherein this is merely intended for better illustration and not limited herein.

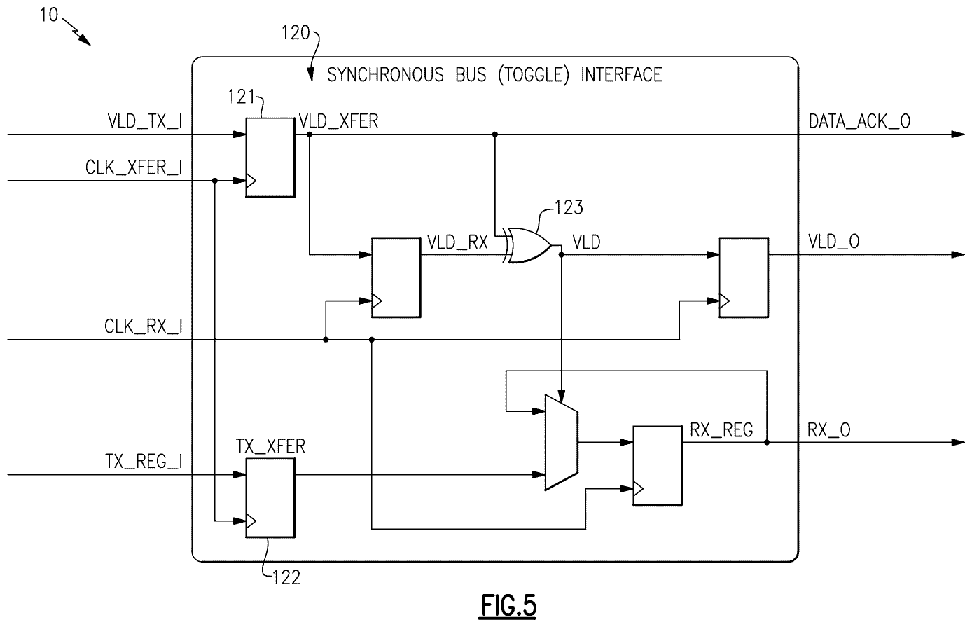

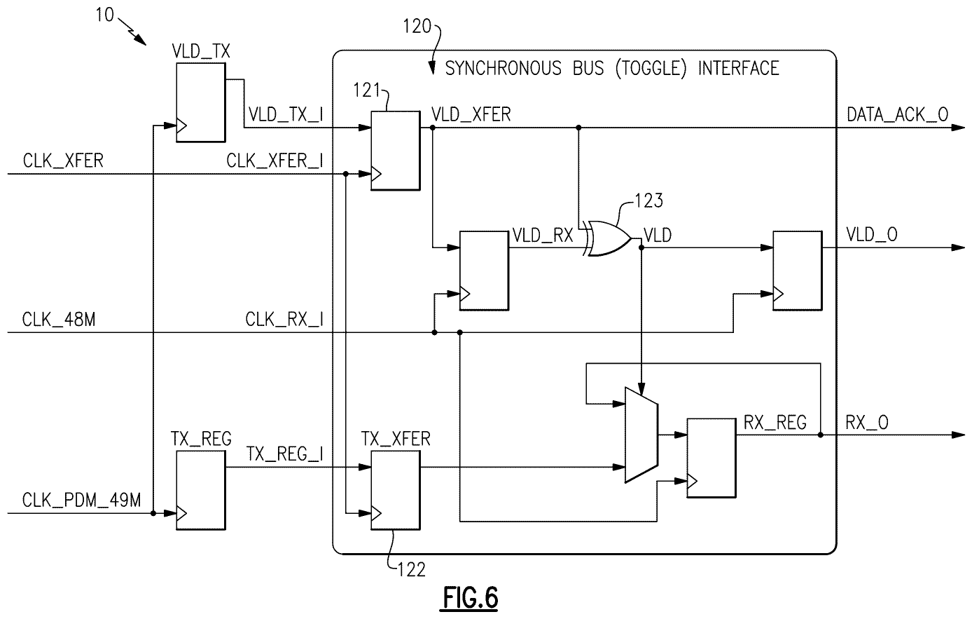

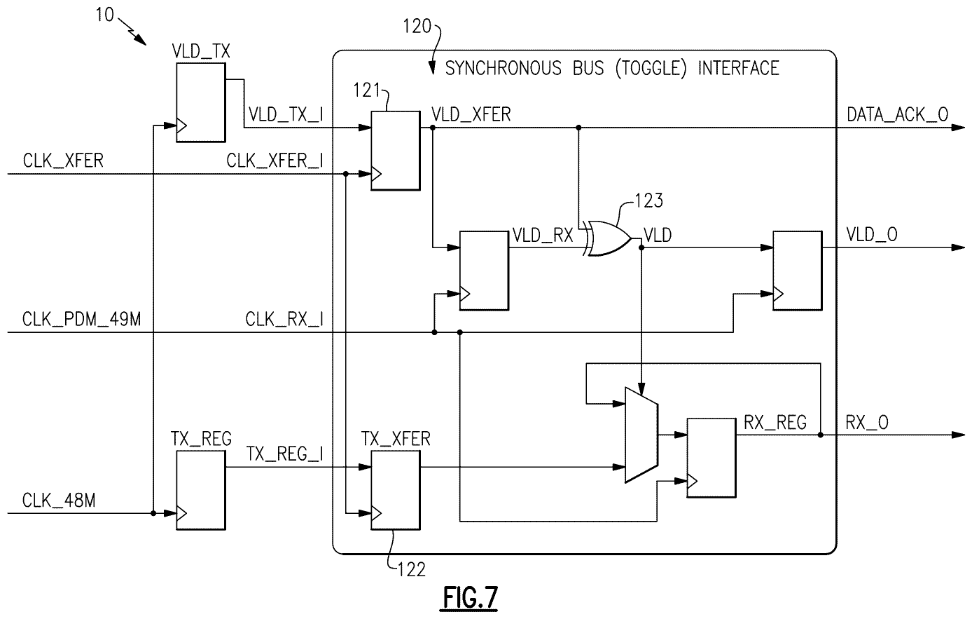

FIG. 5 illustrates in a schematic block and/or circuit diagram the apparatus, e.g. apparatus 100, and/or the synchronous bus interface 10 according to another example. Deviating from the apparatus, e.g. apparatus 100, and/or the synchronous bus interface 10 according to FIG. 3 and FIG. 4, where the input is in level-style, here, the apparatus, e.g. apparatus 100, and/or the synchronous bus interface 10 is configured to support toggle-style input.

Basically, compared to the examples according to FIG. 3 and FIG. 4, in the apparatus, e.g. apparatus 100, and/or the synchronous bus interface 10 according to FIG. 5, merely one gate has been changed and/or modified, which gate is denoted by reference sign 123. It is understood that each time the vld_tx_i input changes state this indicates new data is valid.

FIG. 6 illustrates in a schematic block and/or circuit diagram the apparatus, e.g. apparatus 100, and/or the synchronous bus interface 10 for the above-mentioned toggle-style input for forward transfer of data from the first clock domain clk_pdm_49m domain to the second clock domain clk_48m domain.

In the example according to FIG. 6, the single-bit signal vld_tx_i denotes a valid toggle in the first clock domain clk_pdm_49m. Further, tx_reg_i denotes data from a register in the first clock domain clk_pdm_49m, and the valid toggle, i.e. the single-bit signal vld_tx_i, indicates when it is valid. In addition, vld_o denotes a valid level in the second clock domain clk_48m, and rx_o denotes the data in the second clock domain clk_48m. It is understood that either only the transferred single-bit signal vld_o, or only the transferred data rx_o, or both the transferred single-bit signal vld_o and the transferred data rx_o are captured and used at the output. It is noted that vld_o, rx_o and data_ack_o each denote an output of the apparatus, e.g. apparatus 100, and/or the synchronous bus interface 10. Accordingly, in at least some embodiments, the diagram the apparatus, e.g. apparatus 100, and/or the synchronous bus interface 10 may comprise one or more outputs configured to output the data, i.e. rx_o, in the second clock domain clk_48m.

In at least some embodiments, when data is to be transferred from the first clock domain clk_pdm_49m to the second clock domain clk_48m, the single-bit signal, i.e. the valid toggle vld_tx_i, is to indicate that data, i.e. tx_reg_i, to be transferred is valid. As mentioned above, the sequential circuit 120 comprises the number of second flip-flops 122 clocked by the clock signal clk_xfer_i. The apparatus, e.g. apparatus 100, and/or the synchronous bus interface 10 is configured to sample the data, i.e. tx_reg_i, with the number of second flip-flops 122. Further, the apparatus, e.g. apparatus 100, and/or the synchronous bus interface 10 is configured to gate a respective output of the number of second flip-flops 122 by the single-bit signal, i.e. vld_tx_i, transferred to the second clock domain clk_48m to transfer the data in the second clock domain clk_48m.

Referring to the above exemplary frequencies, since the first clock domain clk_pdm_49m is faster than the second clock domain clk_48m, the valid strobe can switch at most at 24.576 MHz, and data can be transferred at most at 24.576 MHz, wherein this is merely intended for better illustration and not limited herein.

FIG. 7 illustrates in a schematic block and/or circuit diagram the apparatus, e.g. apparatus 100, and/or the synchronous bus interface 10 for the above-mentioned toggle-style input for reverse transfer of data from the first clock domain clk_pdm_49m domain to the second clock domain clk_48m domain.

In the example according to FIG. 7, the single-bit signal vld_tx_i denotes a valid toggle in the second clock domain clk_48m. Further, tx_reg_i denotes data from a register in the second clock domain clk_48m, and the valid toggle, i.e. the single-bit signal vld_tx_i, indicates when it is valid. In addition, vld_o denotes a valid level in the first clock domain clk_pdm_49m, and rx_o denotes the data in the first clock domain clk_pdm_49m. It is understood that either only the transferred single-bit signal vld_o, or only the transferred data rx_o, or both the transferred single-bit signal vld_o and the transferred data rx_o may be captured and used as output. It is noted that vld_o, rx_o and data_ack_o each denote an output of the apparatus, e.g. apparatus 100, and/or the synchronous bus interface 10. Accordingly, in at least some embodiments, the diagram the apparatus, e.g. apparatus 100, and/or the synchronous bus interface 10 may comprise one or more outputs configured to output the data, i.e. rx_o, in the first clock domain clk_pdm_49m.

In at least some embodiments, when data is to be transferred from the second clock domain clk_48m to the first clock domain clk_pdm_49m, the single-bit signal, i.e. the valid toggle vld_tx_i, is to indicate that data, i.e. tx_reg_i, to be transferred is valid. As mentioned above, the sequential circuit 120 comprises the number of second flip-flops 122 clocked by the clock signal clk_xfer_i. The apparatus, e.g. apparatus 100, and/or the synchronous bus interface 10 is configured to sample the data, i.e. tx_reg_i, with the number of second flip-flops 122. Further, the apparatus, e.g. apparatus 100, and/or the synchronous bus interface 10 is configured to gate a respective output of the number of second flip-flops 122 by the single-bit signal, i.e. vld_tx_i, transferred to the first clock domain clk_pdm_49m to transfer the data in the first clock domain clk_pdm_49m.

Referring to the above exemplary frequencies, since the first clock domain clk_pdm_49m is faster than the second clock domain clk_48m, the valid strobe can switch at most at 48 MHz, and data can be transferred at most at 48 MHz, wherein this is merely intended for better illustration and not limited herein.

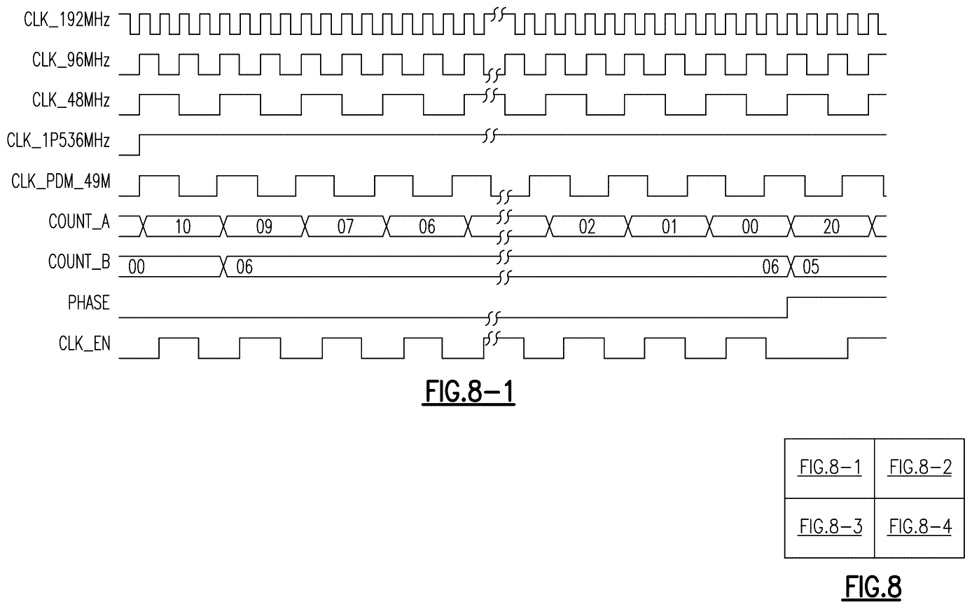

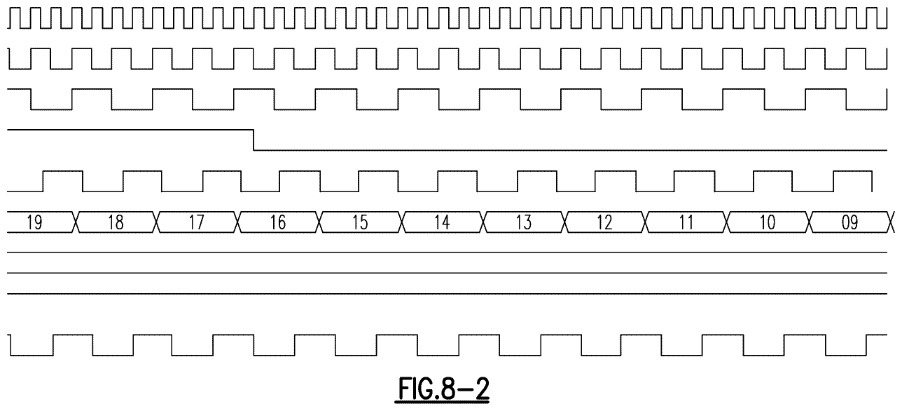

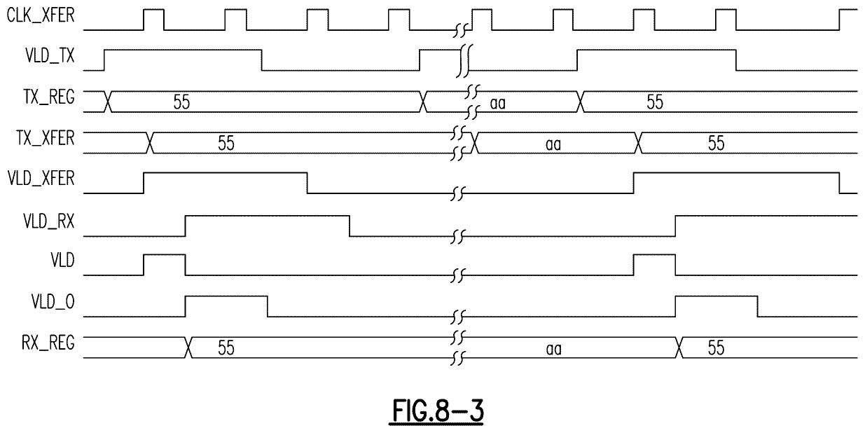

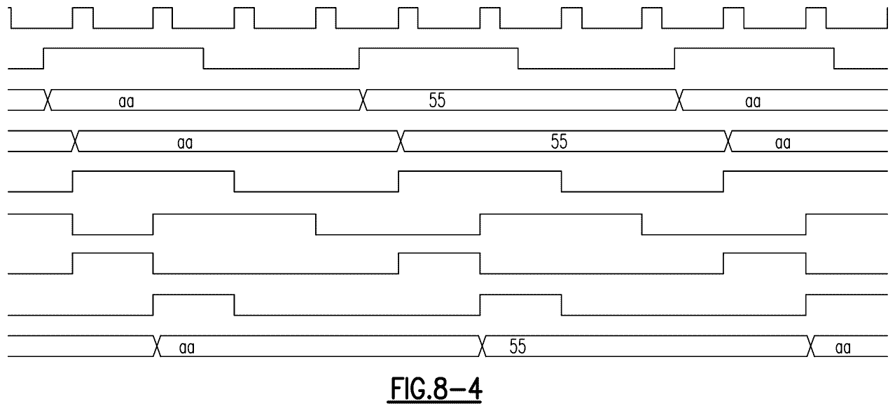

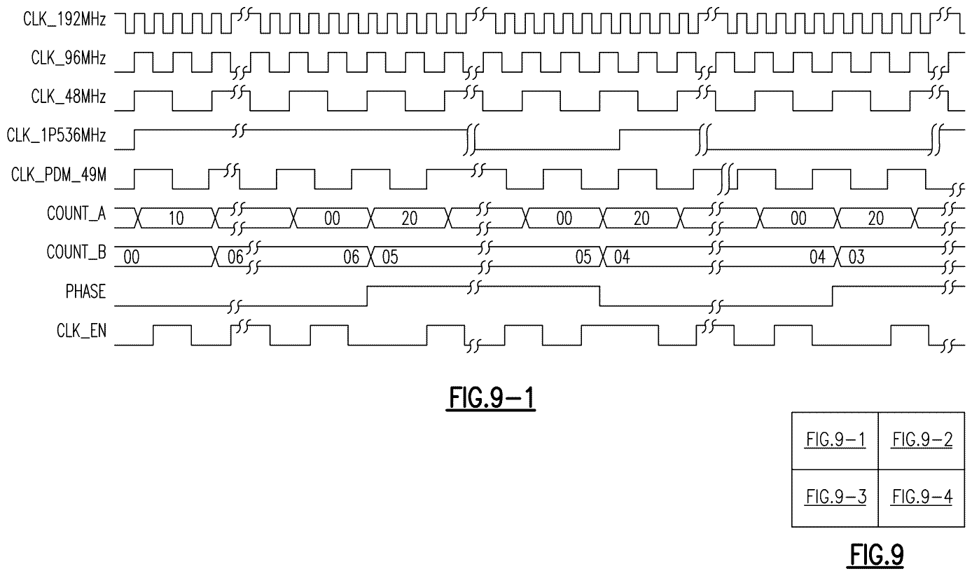

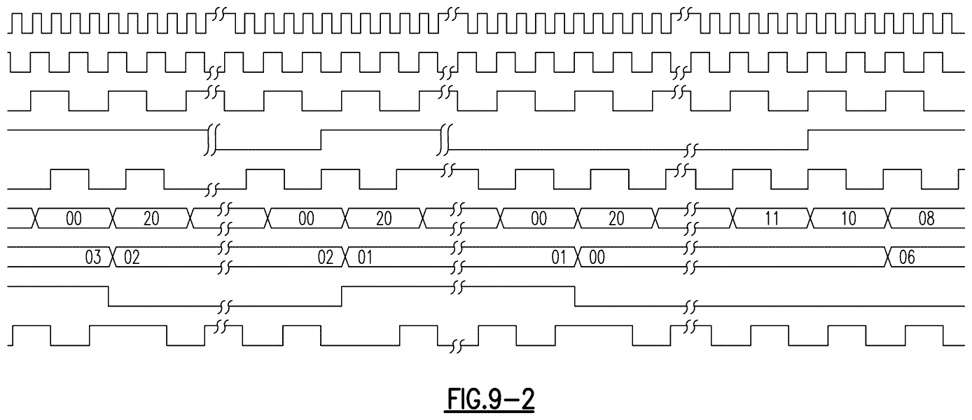

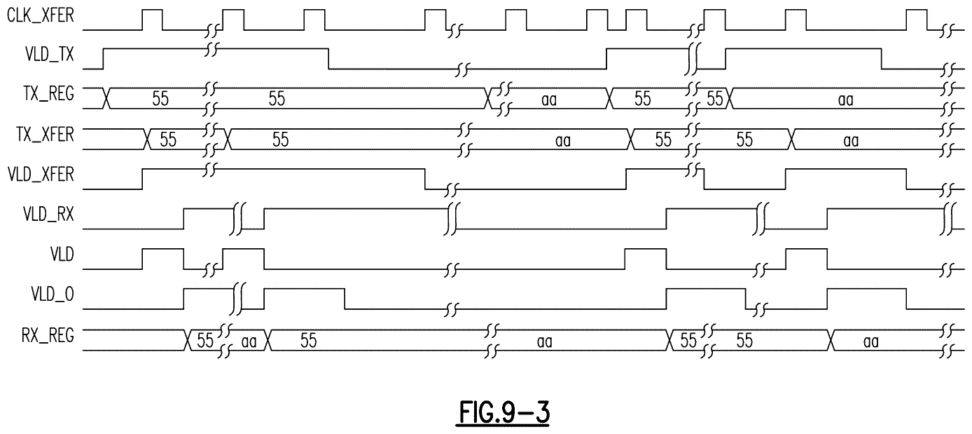

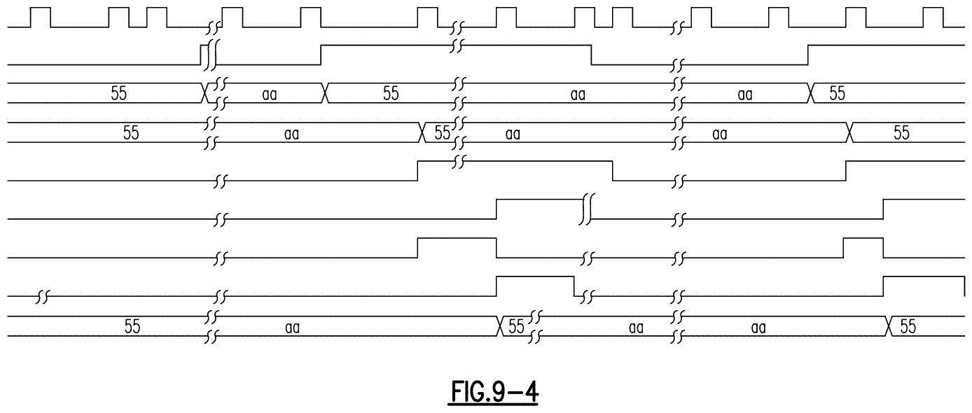

FIG. 8 and FIG. 9 each illustrate in a timing diagram the principle described herein for transferring a single-bit signal and/or data from one clock domain to another. FIG. 8 and FIG. 9 refer to the above-mentioned case where the input is in level-style.

In cycle 0 of clk_48m the positive edges of both clk_48m and clk_pdm_49m perfectly align. In cycle 0 for a single-bit signal crossing from clk_pdm_48m to clk_48m, e.g. the vld signal, the launch clock edge is at 0 while the capture clock edge coincides with negative edge of clk_48m. This means the setup requirement is ½ clk_48m cycle=64 and tt units=10.4167 ns. In the next cycle, the launch clock edge may be 3 tt units earlier relative to the capture clock edge. For cycle 1 the setup requirement is then 67 tt units=10.9049 ns. This continues until the phase signal transitions, which occurs at cycle 10. For cycle 9 the setup requirement is 91 tt units=14.8112 ns. When phase transitions from 0 to 1 the capture clock shifts later by ½ clk_48m cycle=64 tt units. However, the launch clock also shifts later by 1 clk_pdm_49m cycle=125 tt units. For cycle 10 the setup requirement is 91+3+64−125=33 tt units=5.3711 ns. The next phase transition occurs 21 cycles later at cycle 31. For cycle 30 the setup requirement is 93 tt units=15.1367 ns. When phase transitions from 1 to 0 the capture clock shifts earlier by ½ clk_48m cycle=64 tt units. The launch clock does not shift. For cycle 31 the setup requirement is 93+3−64=32 tt units=5.2083 ns. Careful analysis shows that the minimum setup requirement is at cycle 31 and is 5.2083ns.

For example, for a single-bit signal crossing from clk_pdm_48m to clk_48m, there may be a certain amount of built-in hold time due to the alignment of the clock edges, specifically from the launch clock edge to the previous capture clock edge. This may be denoted as the hold time available. For cycle 0, the previous capture clock edge is at −½ clk_48m cycle=−64 tt units=−10.4167 ns. This means the hold time available is 64 tt units=10.4167 ns. In the next cycle the launch clock edge will be 3 tt units earlier relative to the capture clock edge. For cycle 1, the hold time available is then 61 tt units=9.9284 ns. For cycle 10 the hold time available is 34 tt units=5.5339 ns. For cycle 11, the previous capture clock would be affected by the phase transition. For cycle 11 the hold time available is 34−3−64+125=92 tt units=14.9740 ns. For cycle 31 the hold time available is 32 tt units=5.2083 ns. For cycle 33 the hold time available is 32−3+64=93 tt units=15.1367 ns. Careful analysis shows that the minimum hold time available is at cycle 115 and is 30 tt units=4.8828 ns.

It may be understood that in reality, the positive edges of clk_48m and clk_pdm_49m may not align in cycle 0 due to phase shift, e.g. introduced by a PLL, e.g. primarily the phase frequency detector. The PLL may be characterized to set bounds on this phase shift, which may be defined as the delay from the positive edge of clk_pdm_49m and the positive edge of clk_1p536m. Therefore, in reality, the phase shift may meet reasonable bounds such as a minimum of 5 ns and a maximum of 10 ns. To account for this phase shift, the initial count and initial phase may be adjusted to make cycle 0 match the point in the ideal sequence where the positive edges of clk_48m and clk_pdm_49m are offset by 7.5 ns. The edges shift by 3 tt units each clk_48m cycle, so the required point in the ideal sequence is cycle 16, i.e. 7.5 ns/3 tt units=15.4. The initial value for count_a may then be 10+16−21=5 and the initial phase should be set to 1. More analysis with these settings and the phase shift bounds shows that the minimum setup requirement is at cycle 5 and is 2.8581 ns. The minimum hold time available is at cycle 89 and is 2.2331 ns.

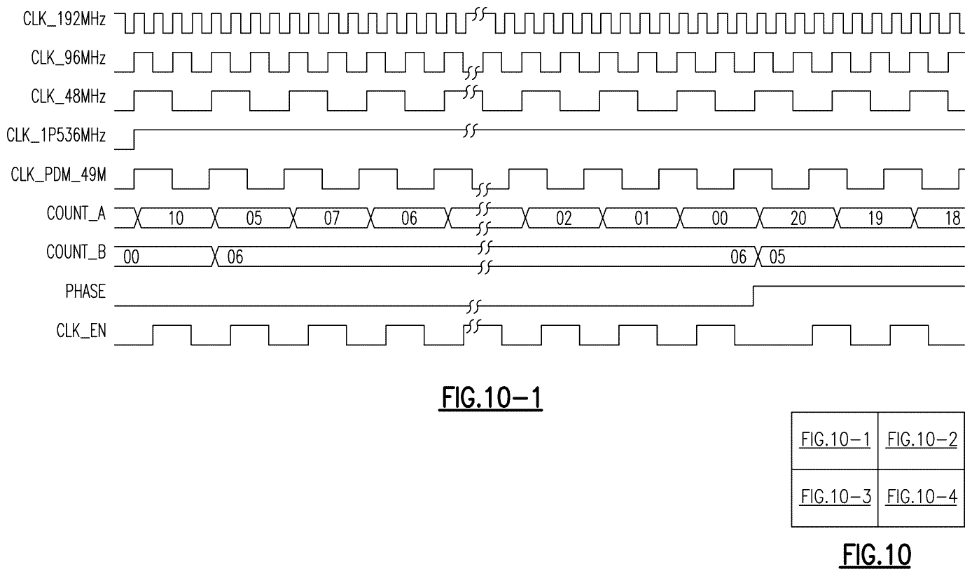

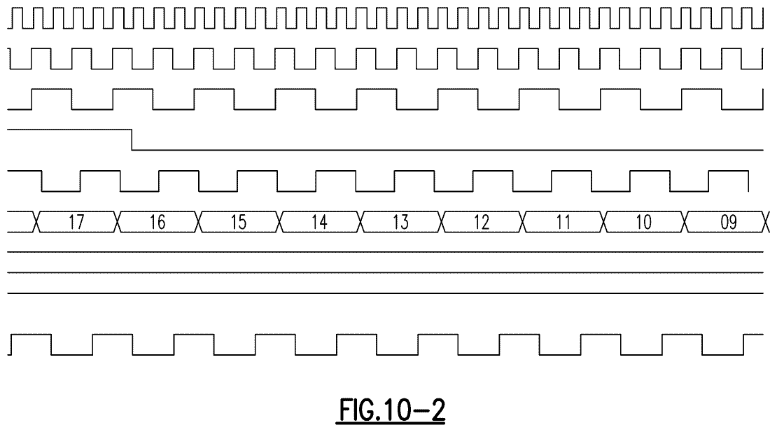

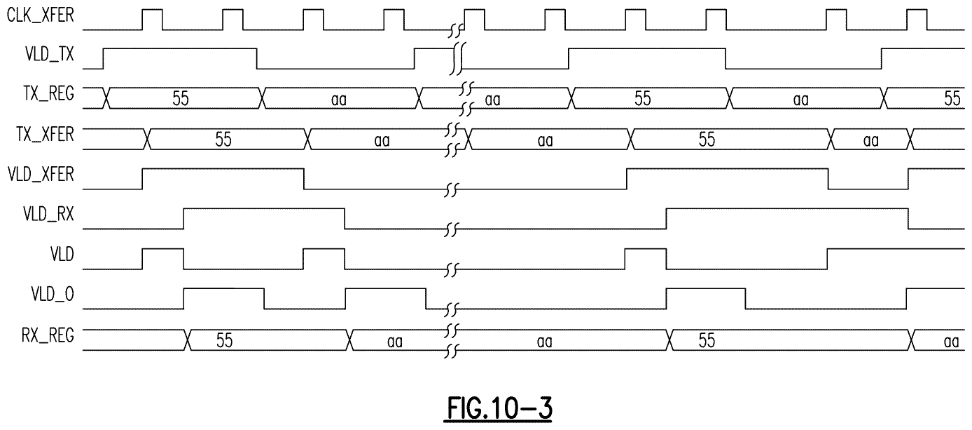

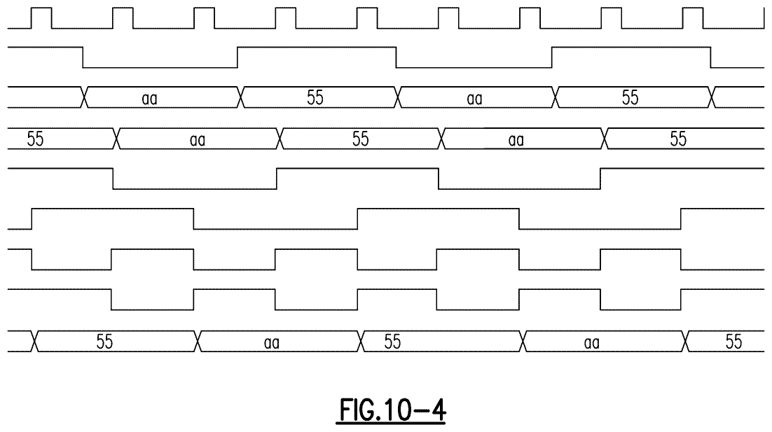

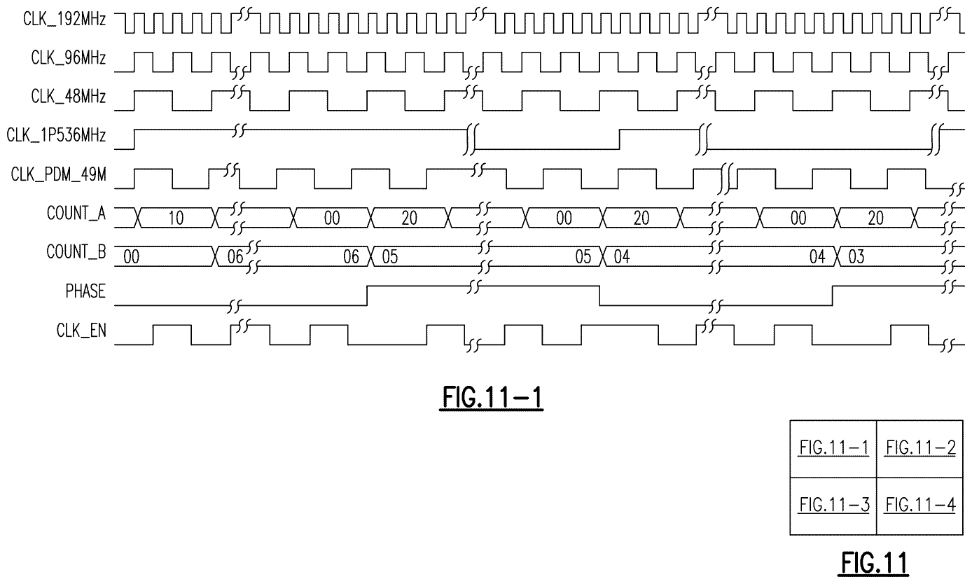

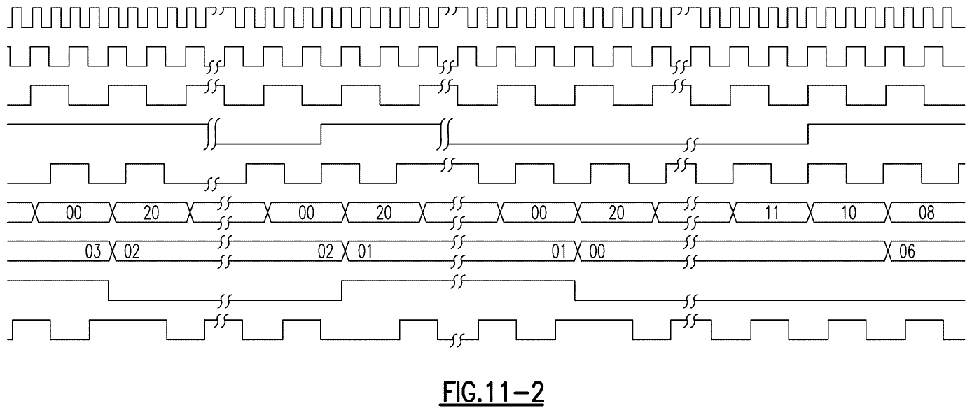

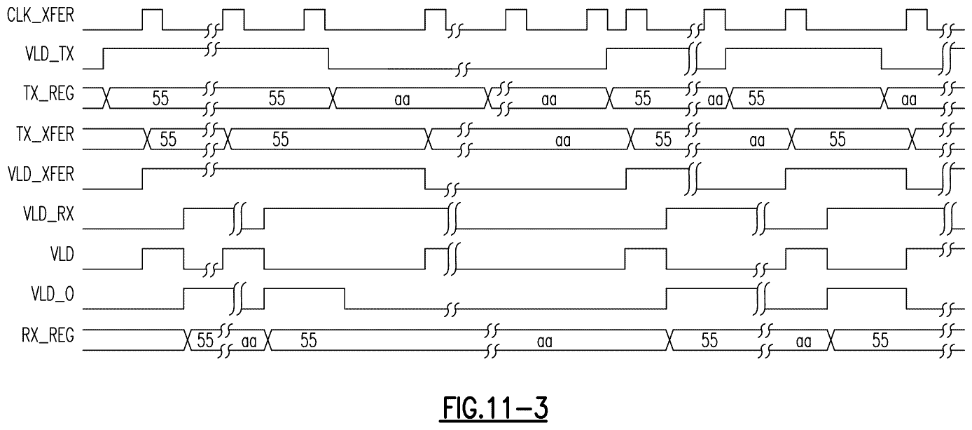

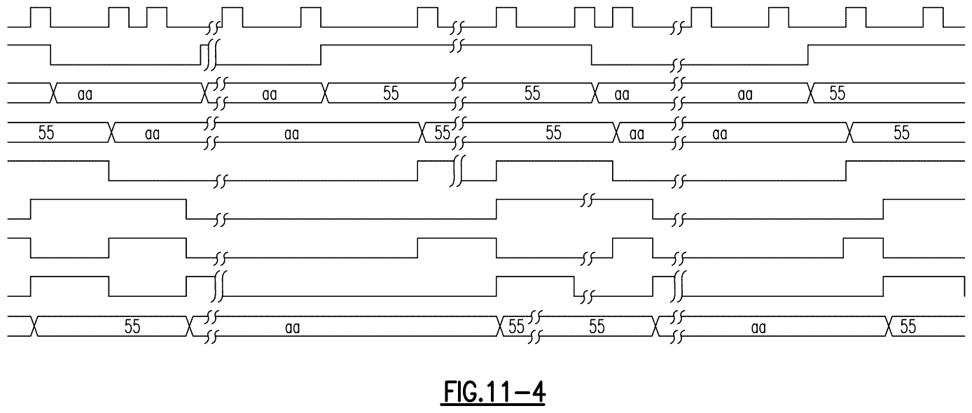

FIG. 10 and FIG. 11 each illustrate in a timing diagram the principle described herein for transferring a single-bit signal and/or data from one clock domain to another. FIG. 10 and FIG. 11 refer to the above-mentioned case where the input is in toggle-style.

FIG. 12 illustrates in a schematic block and/or circuit diagram an example of the clock generator 110 described herein, used for generating the clock signal clk_xfer_i, which in turn is used as input for the apparatus, e.g. apparatus 100, and/or the synchronous bus interface 10. As exemplarily illustrated, the clock generator 110 may comprise a sequential circuit comprising one or more of a number of data storage elements, e.g. flip-flops, a number of gates, or the like. It may be understood that various functionalities associated with the generation of the clock signal clk_xfer_i, i.e. the transfer clock, can be achieved with fewer or more components than depicted in FIG. 10.

In FIG. 12, count_a denotes the above-mentioned first counter and count_b denotes the above-mentioned second counter, each clocked by the second clock domain clk_48m. Further, FIG. 10 illustrates the periodic relationship between the two clock domains, the first clock domain may be or may comprise a 49.152 MHz clock generated by a multiply by 32 of a 1.536 MHz clock, and the second clock domain may be or may comprise a 48 MHz clock generated by a divide by 4 of a 192 MHz clock. The 1.536 MHz clock may be generated by a divide by 125 of the 192 MHz clock. In addition, clk_xfer_o denotes the output of the clock generator 110 and corresponds to the clock signal clk_xfer_i input to the apparatus, e.g. apparatus 100, and/or the synchronous bus interface 10 described herein.

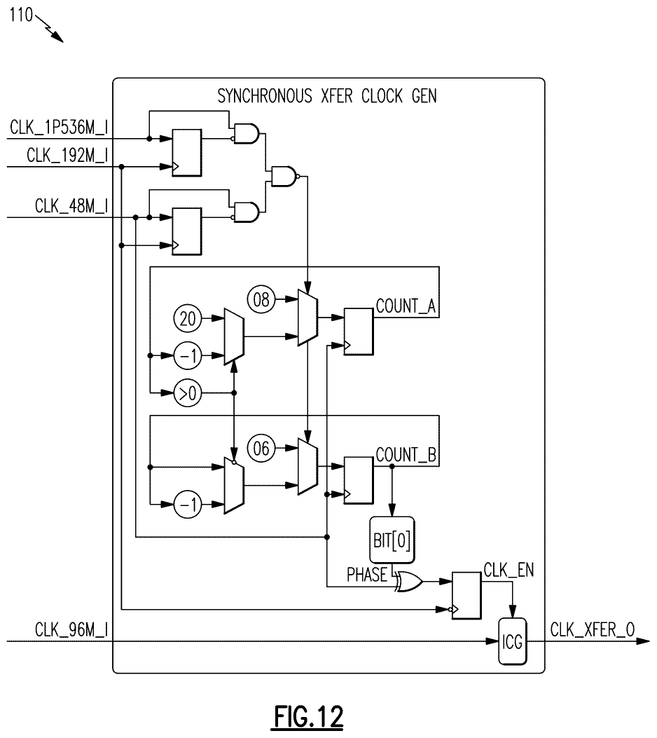

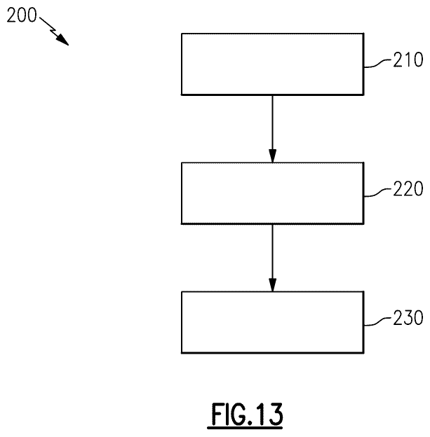

FIG. 13 illustrates in a flow chart an exemplary method 200 for transferring a single-bit signal and/or data from a first clock domain to a second clock domain. The method may be implemented, for example, by the apparatus, e.g. apparatus 100, and/or the synchronous bus interface 10 described herein.

The method comprises receiving 210 a single-bit signal in the first clock domain. The method further comprises generating 220, by a clock generator, a clock signal having a frequency that is a multiple of a frequency of the second clock domain. In addition, the method comprises sampling 230, by using a sequential circuit comprising a first flip-flop clocked by the clock signal, the single-bit signal with the first flip-flop to transfer the single-bit signal to the second clock domain.

In at least some embodiments, the first clock domain and the second clock domain may be periodic with each other.

Further, in at least some embodiments, the frequency of the clock signal may be twice the frequency of the second clock domain.

In at least some embodiments, the clock signal may be generated so that there is one clock pulse in each period of the second clock domain.

Further, in at least some embodiments, in each period of the second clock domain, a pulse of the clock signal is aligned with a rising edge or a falling edge of the second clock domain based on a value of a phase signal.

In at least some embodiments, the phase signal may be derived so that positive edges of the clock signal are farther away from positive edges of the first clock domain.

Further, in at least some embodiments, the transferred single-bit signal may be output in the second clock domain.

In at least some embodiments, data may be transferred from the first clock domain to the second clock domain. The single-bit signal may be used to indicate that data to be transferred is valid. The sequential circuit may comprise a number of second flip-flops clocked by the clock signal. The method may further comprise sampling the data with the number of second flip-flops. Further, the method may comprise gating a respective output of the number of second flip-flops by the single-bit signal transferred to the second clock domain to transfer the data in the second clock domain.

Further, in at least some embodiments, the transferred data may be output in the second clock domain.

Further, in at least some embodiments, the method may comprise timing a path between the first clock domain and the second clock domain in static timing analysis (STA). This can be done since the two clock domains are synchronous. Also, the path from the first clock domain to the transfer clock, i.e. the clock generating the clock signal clk_xfer_i, may be timed in STA since there is a known minimum time difference between their positive edges. Since all paths can be timed in STA, an implementation of the method can be designed to be extremely reliable.

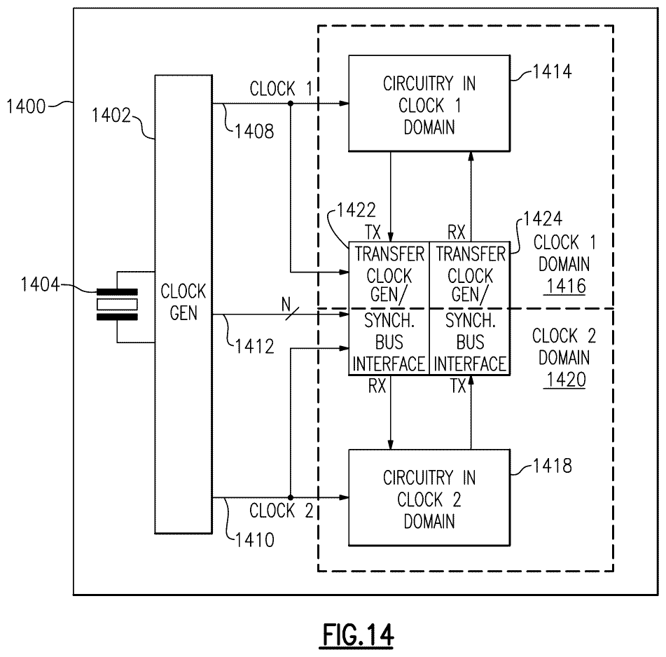

FIG. 14 illustrates a schematic block diagram of an example of an electronic system 1400 that can include any of the circuitry described herein for transferring a single-bit signal and/or data from a first clock domain to a second clock domain, according to an embodiment of the present disclosure. For example, the system 1400 can be a mobile device (e.g., a smart phone, tablet, laptop, wearable or other wireless mobile device) or a sub-system thereof such as a radio frequency front end module, or the system may be included a vehicle such as an automobile, air craft (e.g., manned aircraft or a drone) or a sub-system thereof such as a radio frequency front end module.

The system 1400 includes clock generation circuitry 1402 that receives an input clock from a crystal oscillator 1404 and generates a plurality of clocks including a first clock 1408 having a first frequency, a second clock 1410 having a second frequency, and n additional clocks 1412 each having a corresponding frequency. For example, the clock generation circuitry 1402 can include dividers, phase-locked loops, and other appropriate components for generating clocks of various frequencies. In some embodiments, the first clock 1408 is a 49.152 MHz clock generated by a multiply by 32 of a 1.536 MHz clock, which is included in the n additional clocks 1412, and the second clock 1410 is a 48 MHz clock generated by a divide by 4 of a 192 MHz clock, which is also included in the n additional clocks 1412.

The illustrated system 1400 also includes first circuitry 1414 residing in a first clock domain 1416 and driven by the first clock 1408 and second circuitry 1418 residing in a second clock domain 1420 driving by the second clock 1410. For example, while a wide variety of different kinds of circuitry can be included, in some embodiments, the first circuitry 1414 comprises digital circuitry (e.g., one or more microcontrollers) of a radio frequency front end system and the second circuitry 1418 comprises analog circuitry of the front end system, which can include some or all of transistor-based transmit amplifiers, receive amplifiers, radio frequency switches, filters, and the like.

In addition, the illustrated system 1400 includes a first synchronization interface 1422 configured to allow robust transfer of information between the first clock domain 1416 and the second clock domain 1420, and a second synchronization interface 1424 configured to allow robust transfer of information between the second clock domain 1420 and the first clock domain 1416. The first synchronization interface 1422 and the second synchronization interface 1424 can each include any of the synchronization bus interfaces described herein, e.g., the apparatus 100 of FIG. 1, any of the synchronization bus interfaces 10 of FIGS. 2-7, and either of the transfer clock generators 110 of FIG. 1 or 12. For example, in some embodiments, the first clock 1408 is 49.152 MHz, the second clock 1410 is 48 MHz, the first synchronization interface 1422 includes the transfer clock generator 110 of FIG. 12 and the synchronization but interface 10 of FIG. 3, and the second synchronization interface 1424 includes the transfer clock generator 110 of FIG. 12 and the synchronization bus interface 10 of FIG. 4.

### Applications

Some of the embodiments described above have provided examples in connection with electronic devices. However, the principles and advantages of the embodiments can be used for any other systems or apparatus that have needs for transferring single-bit signals and/or data from one clock domain to another.

### Conclusion

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A method for transferring at least a first signal from a first clock domain to a second clock domain, the method comprising:
receiving a first signal representing a first data bit in the first clock domain;
generating, by a clock generator, a clock signal having a frequency that is a multiple of a frequency of the second clock domain;
sampling, by using a sequential circuit including a first flip-flop clocked by the clock signal, the first signal with the first flip-flop to transfer the first signal to the second clock domain.

2. The method of claim 1 wherein the first clock domain and the second clock domain are periodic with each other.

3. The method of claim 1 wherein the frequency of the clock signal is twice the frequency of the second clock domain.

4. The method of claim 1 wherein the clock signal is generated so that there is one clock pulse in each period of the second clock domain.

5. The method of claim 1 wherein, in each period of the second clock domain, a pulse of the clock signal is aligned with a rising edge or a falling edge of the second clock domain based on a value of a phase signal.

6. The method of claim 5 wherein the phase signal is derived so that positive edges of the clock signal are farther away from positive edges of the first clock domain.

7. The method of claim 1 further comprising outputting the first signal in the second clock domain.

8. The method of claim 1 wherein one or more additional signals representing one or more additional data bits are to be transferred from the first clock domain to the second clock domain, the first signal is to indicate that the one or more additional signals to be transferred are valid, the sequential circuit includes a number of second flip-flops clocked by the clock signal, and the method further includes:
sampling one or more additional signals with the number of second flip-flops; and
gating a respective output of the number of second flip-flops by the first signal transferred to the second clock domain to transfer the one or more additional signals to the second clock domain.

9. The method of claim 8 further comprising outputting the transferred one or more additional signals in the second clock domain.

10. The method of claim 8 wherein the first signal indicates by its signal level whether or that the one or more additional signals to be transferred are valid.

11. The method of claim 8 wherein the first signal indicates by its changing state whether or that the one or more additional signals to be transferred are valid.

12. An apparatus for transferring at least a first signal from a first clock domain to a second clock domain, the apparatus comprising:
a clock generator configured to generate a clock signal having a frequency that is a multiple of a frequency of the second clock domain; and
a sequential circuit including a first flip-flop configured to receive a first signal representing a first data bit in the first clock domain and to receive the clock signal, the sequential circuit being configured to sample the first signal with the first flip-flop to transfer the first signal to the second clock domain.

13. The apparatus of claim 12 wherein the first clock domain and the second clock domain are periodic with each other.

14. The apparatus of claim 12 wherein the frequency of the clock signal is twice the frequency of the second clock domain.

15. The apparatus of claim 12 wherein the clock signal is generated so that there is one clock pulse in each period of the second clock domain.

16. The apparatus of claim 12 wherein a pulse of the clock signal is aligned with a rising edge or a falling edge of the second clock domain based on a value of a phase signal.

17. The apparatus of claim 16 wherein the phase signal is derived so that positive edges of the clock signal are farther away from positive edges of the first clock domain.

18. The apparatus of claim 12 wherein one or more additional signals representing one or more additional data bits are to be transferred from the first clock domain to the second clock domain, the first signal is to indicate that the one or more additional signals to be transferred are valid, the sequential circuit includes a number of second flip-flops clocked by the clock signal, and the apparatus is further configured to:
sample the one or more additional signals with the number of second flip-flops; and
gate a respective output of the number of second flip-flops by the first signal transferred to the second clock domain to transfer the one or more additional signals to the second clock domain.

19. The apparatus of claim 18 wherein the first signal indicates by its signal level whether or that the one or more additional signals to be transferred are valid.

20. A synchronous bus interface for transferring at least one of a first signal and data from a first clock domain to a second clock domain, the synchronous bus interface comprising:
a clock generator configured to generate a clock signal having a frequency that is a multiple of a frequency of the second clock domain;
a sequential circuit coupled to the clock generator and including a first flip-flop configured to receive a first signal in the first clock domain and to receive the clock signal, the sequential circuit being configured to sample the first signal with the first flip-flop to transfer the first signal to the second clock domain; and
an output coupled to the sequential circuit.
